(19) United States
(12) Patent Application Publication
(10) Pub. No.: US 2010/0313940 A1
(43) Pub. Date: Dec. 16, 2010

(54) PHOTOVOLTAIC ASSEMBLY COMPRISING AN OPTICALLY ACTIVE GLASS CERAMIC

(76) Inventors: Ralf Boris Wehrspohn, Halle (DE); Stefan Schweizer, Paderborn (DE)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/677,535

(22) PCT Filed: Sep. 9, 2008
(86) PCT No.: PCT/DE2008/001507

§ 371 Date: Aug. 26, 2010

(30) Foreign Application Priority Data
Sep. 11, 2007 (DE) 10 2007 043 215.3

(51) Int. Cl. H01L 31/04; H01L 31/18

(52) U.S. Cl. 136/254; 438/63; 977/773; 438/69; 438/96; 257/E31.032; 257/E31.04

(57) ABSTRACT

A solar cell and a method for producing a solar cell are described, comprising at least one photovoltaic layer region (1) which at least partially absorbs photons (6) incident therein, whose photon energy is greater than a minimum photon energy Eₘᵢₙ, and releases electrical charge carriers in the form of electron-hole pairs, which are spatially separable within the photovoltaic layer region (1) and can be tapped via at least two electrodes (2), which are electrically connected to the photovoltaic layer region (1), to implement an electrical voltage, and comprising at least one interaction layer (3 and/or 4), which at least partially overlaps the photovoltaic layer region, in which at least a part of the incident photons (6) are subject to an interaction with emission of photons of higher or lower photon energy than that of the incident photons. The invention is distinguished in that the at least one interaction layer (3 and/or 4) has a matrix structure, in which locally delimited areas having optically active material, which has the structure and size of crystalline nanoparticles, are provided and interact with the incident photons (6).

### BACKGROUND OF THE INVENTION

1. Field of the Invention

The invention relates to a solar cell and a method for producing a solar cell, which comprises at least one photovoltaic layer region and at least one interaction layer, in which an up-conversion or a down-conversion of photons occurs so that a broader component of the solar spectrum can be converted into electrical energy in the solar cell.

2. Description of the Prior Art

Solar cells convert the energy of sunlight directly into electrical power. Solar cells based on semiconductors have been most widespread up to this point, which above all exploit the solar spectrum in the range of the visible and near-infrared range depending on the semiconductor material. The solar cells based on semiconductors essentially comprise a p-doped semiconductor layer and an n-doped semiconductor layer, which are situated between two electrodes. At the boundary surface between p-layer and n-layer, the p-n junction, a space charge region is implemented by diffusion of charge carriers, which results in an electrical voltage which can be tapped from the electrodes.

If a photon of sufficient energy, that is, having an energy greater than the bandgap energy E_{g} of the semiconductor material, reaches this space charge region, it is absorbed at a specific absorption probability and excites an electron from the valence band of the semiconductor material into the conduction band of the semiconductor material. A hole arises in the valence band. The electron excited into the conduction band and the hole form a so-called electron-hole pair. The electron-hole pair is spatially separated by the potential difference applied over the space charge region. The electron and the hole from a pair travel in opposing directions to the electrodes, whereby an electrical current flow is finally generated.

Only photons having a minimum energy, which at least corresponds to the bandgap energy of the semiconductor, may be converted into electrical power, so that the theoretically achievable efficiency for converting photon energy into electrical power from sunlight with the aid of typical solar cells is limited. In addition, for example, upon the generation of an electron-hole pair in a semiconductor solar cell having a high-energy photon, that is, a photon whose energy is significantly greater than the bandgap, for example, greater than two times E_{g}, a greater part of the photon energy is lost by thermalization, as a non-radiant energy discharge of the generated charge carriers. For these reasons, for example, the theoretically achievable efficiency of silicon solar cells is at most 30%. The practically achievable efficiency, in which the absorption probability is additionally included, is far less.

In addition to solar cells based on semiconductors, approaches are also known for producing solar cells from other materials. Organic solar cells or dye-sensitized solar cells are cited as examples. However, only low efficiencies have also been achieved here up to this point.

Therefore, various efforts have been made to improve the efficiency of solar cells. One possibility for improving the efficiency comprises the targeted exploitation of a broader spectral component of the sunlight.

So-called tandem cells, which have at least two different semiconductor layer regions situated one above another, each of which forms two photovoltaic layers, with solar cell regions having varying energetic bandgap, are known. Photons whose energy is less than the bandgap of the first semiconductor material and which therefore penetrate this first semiconductor material nearly without loss may be absorbed in the second, adjoining solar cell having smaller bandgap, if their energy is greater than the bandgap of the second semiconductor material.

Furthermore, providing energetic intermediate levels in the bandgap by targeted introduction of impurities into the semiconductor material is known, whereby even photons having a lower energy than the bandgap may excite electrons via the intermediate level into the conduction band. The disadvantage in this case, however, is that additional non-radiant recombination channels for electron-hole pairs are also provided by the intermediate level, by which the desired improvement of the efficiency increase is only possible in a limited manner.

A further possibility for the efficiency increase of solar cells comprises situating layers outside the actual solar cell, that is, the photovoltaic layer region in which the absorption and charge separation occur, in which an up-conversion or a down-conversion of the photon energy occurs in the course of two-photon or multiphoton processes. Higher-energy photons are generated from lower-energy photons upon the up-conversion and at least one lower-energy photon is generated from higher-energy photons upon the down-conversion, the generated photons each having sufficient energy so that they may generate charge carriers in the photovoltaic layer.

Assemblies are disclosed for this purpose in WO 03/079457 A1, in which the actual solar cell is optically coupled to a monocrystalline up-conversion layer including reflector layer and/or a monocrystalline down-conversion layer, whereby increases of the theoretically achievable efficiency to greater than 60% are achievable. The disadvantage in this case, however, is that a production of such monocrystalline conversion layers is costly and therefore does not appear cost-effective for the large-scale manufacturing of solar modules.

Furthermore, work of Gibart et al., is also known, published in Jap. J. Appl. Phys.; 35; 1996; 4401, in which a ceramic doped with rare earth elements was situated in the transmission direction behind a gallium arsenide solar cell with the purpose of increasing the efficiency and/or the quantum yield by up-conversion of lower-energy photons (E<E_{g}). However, Gibart et al. came to the conclusion that a practical application of the up-conversion did not appear effective, because efficiencies of only 2.5% were achievable using these measures under excitation in the infrared spectral range (1 W power).

### SUMMARY OF THE INVENTION

The problem comprises refining a solar cell comprising at least one photovoltaic layer region, which at least partially absorbs photons incident therein, whose photon energy is greater than a minimum photon energy Eₘᵢₙ, and releases electric charge carriers in the form of electron-hole pairs, which are spatially separable within the photovoltaic layer region and can be tapped via at least two electrodes electrically connected to the photovoltaic layer region while implementing an electrical voltage, and comprising at least one interaction layer, which at least partially overlaps the photovoltaic layer region, and in which at least a part of the incident photons are subject to an interaction with emission of photons of higher or lower photon energy than that of the incident photons, and a method for producing such a solar cell so that it has an improved efficiency, it is producible cost-effectively in industrial scale, and it allows an improvement and broadening of its possible technical uses.

A solar cell can be refined in such a manner that the interaction layer has a matrix structure, in which local regions having optically active material, of crystalline nanoparticles, are provided, with which the incident photons interact.

According to the invention, high quantum yields for the processes of up-conversion and down-conversion are not only achievable in monocrystalline layers, but rather even crystalline nanoparticles display a high quantum yield. By embedding the nanoparticles in a matrix structure, interaction layers may be produced, which may be adapted to greatly varying demands, which, for example, a monocrystal of a corresponding optical material cannot fulfill. In particular, many phosphors are mechanically brittle and are sometimes even water-soluble or hygroscopic. By embedding systems of this type in a suitable matrix, improved mechanical and chemical stability can be obtained. In addition, the complex and costly production of large monocrystalline layers can be avoided. Many novel possible implementations may be derived from the invention by embedding optically active nanocrystals in a matrix, which is not possible according to the prior art.

In a particularly preferred embodiment, the matrix structure is amorphous. Thus, implementing the interaction layer in the form of a glass ceramic is a particularly suitable manner. The glass ceramic comprises a glass matrix in which optically active nanoparticles are embedded. Glass ceramics have particularly favorable thermomechanical properties. The thermal coefficient of expansion is settable to particularly be extensively variable; to even be negative or zero. A further advantage is the mechanical strength and the cost-effective production.

A plastic matrix is similarly suitable as the matrix structure. By introducing the optically active nanoparticles into a plastic matrix, flexible interaction layers may additionally be produced, which are suitable for the use of solar cells in so-called wearables, for example. Wearables are pieces of clothing in which greatly varying technical devices, such as environmental sensors having associated electronics, monitoring units, communication unit, devices for augmented reality, etc., are integratable.

In a further preferred embodiment, the optically active material contains nanophosphors such as alkaline/alkaline earth halogenide compounds doped with rare earth elements as well as aluminates and borates, but also silicates, oxides, sulfates, or phosphates.

By introducing rare earth elements into the nanocrystals, energetic intermediate levels may be generated in the nanocrystal, which are usable for the conversion of the photon energy of incident photons. The quantum yield for the conversion is particularly high with the nanoparticles of the invention, because the rare earth elements obtain a crystalline environment, and recombinations of photons via non-radiant processes are significantly reduced. An up-conversion or a down-conversion occurs in the optically active material by the selection of a corresponding rare earth element, that is, a higher-energy photon is generated from two lower-energy photons or at least one lower-energy photon is generated from a higher-energy photon.

In a further preferred embodiment, the optically active material includes an organic dye. These organic dyes are typically constructed from multiple aromatic rings, such as fluorescein or rhodamine.

The optically active material is preferably selected so that the photons emitted from the interaction with photons have photon energies which are in the absorption range of the photovoltaic layer region of the solar cell. By suitable selection of the optically active material, the quantum yield for generating electron-hole pairs and thus the efficiency of the entire solar cell assembly can be significantly increased.

Solar cells are typically provided with a cover glass and/or a cover layer transparent to sunlight, at least for reasons of protection from external influences. Therefore, the interaction layer is provided like a cover layer for protecting the photovoltaic layer region in relation to external influences. Only the assembly according to the invention of the interaction layer in the form of a matrix having embedded nanoparticles allows the interaction layer to be implemented, for example, to be resistant to environmental influences, such as moisture or chemicals, and also sufficiently mechanically stable in relation to mechanical strains, such as wind load or snow pressure.

Furthermore, it is advantageous to at least partially cover the photovoltaic layer region, which forms the actual solar cell together with the electrodes, on opposing lateral surfaces with at least one interaction layer implemented according to the invention. One of the two interaction layers contains optically active material, in which a down-conversion occurs. The other of the at least two interaction layers contains optically active material, in which an up-conversion occurs. The interaction layers may each be provided indirectly or directly on the particular lateral surfaces of the photovoltaic layer region. Introducing a type of contact layer between the interaction layers and the photovoltaic layer region advantageously, ensures that the photons which are generated in the interaction layer are coupled as loss-free as possible into the photovoltaic layer region, and are not reflected at the corresponding boundary surfaces because, for example, unfavorable index of refraction ratios.

The interaction layer in which the down-conversion occurs is used as a light entry layer is thus situated facing toward the light incidence. In addition, it is favorable to provide the other interaction layer, in which the up-conversion occurs, with a reflector layer on the rear, that is, facing away from the photovoltaic layer region, at which photons are generated in the up-conversion layer and are emitted in a spatial angle range facing away and/or the incident photons which pass through all layers without interaction are at least partially reflected, so that these photons may pass the photovoltaic layer region or pass it again. In this way, the absorption rate and the efficiency in the generation of electron-hole pairs may be noticeably increased. This reflector layer can either be applied directly to the interaction layer or also in another way, for example, non-galvanically.

As already noted, the interaction between the incident photons and the optically active material is based on one-photon or multiphoton processes. It is thus particularly advantageous if the down-conversion layer is implemented so that more than one photon having a matching energy for the photovoltaic layer region is generated in the context of the down-conversion of a high-energy photon. This results in a further increase of the quantum yield and thus the efficiency.

In a further preferred embodiment, the interaction layer is optically transparent in a spectral range from 350 nm to 1100 nm. In particular through the selection of the concentration of the nanoparticles in the glass matrix, the interaction layer may be made sufficiently transparent and nonetheless high quantum yields may be implemented.

The solar cell according to the invention may particularly advantageously be produced using a method of the following method steps: in a first step, providing the at least one interaction layer, which has a matrix structure, in which optically active crystalline nanoparticles are contained. In a second step, applying at least one interaction layer at least partially indirectly or directly on a technical surface of the photovoltaic layer region. Alternatively thereto, the possibility also exists of using the at least one interaction layer as a substrate for applying the photovoltaic layer region.

Through the configuration according to the invention of crystalline optically active nanoparticles in a matrix structure, both the optical and also mechanical properties of the interaction layer may be set extensively independently of one another. Correspondingly, there is a plurality of method variants, which are founded in greatly varying combinations of matrix structure and nanocrystals.

In a preferred method variant, a first interaction layer is applied at least partially overlapping indirectly or directly on a first technical surface of the photovoltaic layer region. Depending on whether the photovoltaic layer region including the electrode assembly, that is to say the solar cell, is already provided as a type of semi-finished product, a combination of this type with the interaction layer can be performed. Otherwise, the interaction layer may be used as a substrate, on which the production of the solar cell per se is possible.

Subsequently, a second interaction layer is applied at least partially indirectly or directly on a second technical surface of the photovoltaic layer region, which is opposite to the first technical surface. The interaction layers each cause an up-conversion or a down-conversion of incident photons so that the emitted photons have an energy content which is optimal for the photovoltaic layer region. A layer sequence of the following type is particularly preferred in the direction of incidence of the photons: first the down-conversion layer, then the photovoltaic layer region, and subsequently the up-conversion layer region.

In a further preferred method, a technical surface of the first or the second interaction layer is at least partially indirectly or directly provided with a reflector layer. This is particularly a technical surface of an up-conversion layer in this case, which faces away from the photovoltaic layer region. In this way, photons which have passed through the photovoltaic layer region without interaction are reflected back therein. This in turn results in an increase of the quantum yield and thus the efficiency of the entire solar cell assembly.

In a further preferred method, the at least one interaction layer is provided in the form of a glass-ceramic layer, in whose glass matrix optically active material in the form of crystalline nanoparticles is contained. Glass ceramics have outstanding mechanical, in particular thermomechanical properties. In particular, the thermal coefficient of expansion of the glass-ceramic layer is to be noted, which can be set by suitable dimensioning in wide ranges, even to negative values. This offers special advantages, because the coefficient of expansion of the glass ceramic can be adapted to the other materials to which the glass ceramic is to be connected. In this way, tensions because of temperature in the material composite may be avoided, which results in a reduction of the susceptibility to damage.

In addition, glass ceramics may be produced cost-effectively and in large dimensions, so that, for example, glass ceramics in which down-conversion occurs may be used as cover glasses for already existing solar cells/solar modules, as a replacement of the cover glasses used up to this point.

It is particularly advantageous to provide the at least one interaction as a high-temperature glass ceramic, so that the interaction layer can be used as a substrate material, on which semiconductor layers, which form the photovoltaic layer region, can be applied or deposited directly in the context of a production process of the photovoltaic layer region. The particular advantage in this case is in the high achievable quantum yield, because the interaction layer region and the photovoltaic layer region are optimally optically coupled, that is, in particular without air gaps, at which photons from the interaction layer region are reflected.

Furthermore, it is advantageous to introduce an intermediate layer for better optical coupling between at least one interaction layer and the technical surface of the photovoltaic layer region, that is, an adaptation of the indices of refraction of interaction layer and solar cell. Intermediate layers having an index of refraction, which is selected so that photons are coupled from the interaction layer into the photovoltaic layer region, directly increase the quantum yield and thus in turn the efficiency of the solar cell assembly.

In a particularly preferred variant, the at least one interaction layer is obtained by producing a glass melt, into which the optically active material is admixed in the form of crystalline nanoparticles. For example, a melt made of fluoride glass to which erbium and chlorine ions and ions from the group of rare earth elements are added is suitable as the glass melt. Crystalline nanoparticles are implemented in the glass melt by temperature treatment, to which at least a part of the ions from the group of rare earth elements adhere and/or in which at least a part of the ions from the group of rare earth elements is incorporated. The temperature treatment is performed close to the glass transition temperature, which is not necessarily in a protective gas atmosphere.

Nanocrystals doped with erbium ions, which convert photons of lower energy into photons of higher energy in an up-conversion layer, are, for example, suitable as the nanoparticles. Europium ions, which convert the photons of higher energy into lower-energy photons in single-photon processes, are suitable, for example, for the purposes of down-conversion. If a mixture of europium and gadolinium ions is admixed to the glass melt, photons of higher energy may be converted into photons of lower energy in the context of so-called two-photon processes.

### BRIEF DESCRIPTION OF THE DRAWINGS

The invention is explained for exemplary purposes hereafter on the basis of exemplary embodiments with reference to the drawings without restriction of the general idea of the invention. In the figures:

FIG. 1 shows a very schematic assembly of a solar cell according to the invention according to the first exemplary embodiment comprising a photovoltaic layer region, with layers situated parallel to the cover glass.

FIG. 2 shows a very schematic assembly of a solar cell according to the invention according to the second exemplary embodiment having a photovoltaic layer region, with layers situated parallel to the incident radiation.

### DETAILED DESCRIPTION OF THE INVENTION

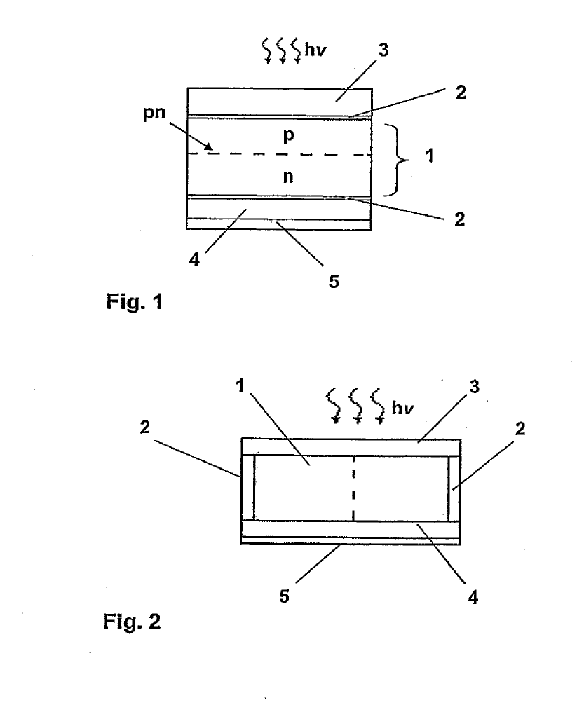

FIG. 1 shows a photovoltaic layer region (1), which is contacted via two electrode assemblies situated in the layers. For example, the photovoltaic layer region 1 can be implemented by one p-doped semiconductor layer and one n-doped semiconductor layer. A space charge region is implemented at the boundary surface between the p-doped layer and the n-doped layer, the p-n junction, and a potential difference arises over the space charge region, which can be tapped at the electrodes in the form of an electrical voltage.

Photons hv having a minimum energy Eₘᵢₙ may be absorbed in the space charge region, one electron from the valence band being raised into the conduction band of the semiconductor. In this way, a freely moving electron arises in the conduction band and a freely moving hole arises in the valence band. One electron-hole pair accordingly arises per absorbed photon. This pair is spatially separated by the potential difference implemented at the p-n junction. The freely moving hole and the freely moving electron travel to one or the other electrode 2 and generate an electrical current flow between the electrodes 2.

The electrode assemblies 2 are to be extensively transparent to the incident photons hv in the assembly shown in FIG. 1. For example, they may be implemented by transparent ITO electrodes or by specially structured electrodes, which do not cover the entire surface of the photovoltaic layer region, so that photons may be coupled into the photovoltaic layer region.

A first interaction layer 3 and a second interaction layer 4 adjoin the electrodes 2. The interaction layer 3 preferably corresponds to a down-conversion layer, in which high-energy photons interact with the down-conversion layer so that one or more photons of lower energy are emitted. The energy of the emitted photons is ideally in the absorption range of the photovoltaic layer region 1.

The interaction layer 4 is implemented as an up-conversion layer, in which the photons hv which have insufficient energy to be absorbed in the interaction layer 3 or in the photovoltaic layer region 1 are converted into a higher-energy photon in the context of a multiphoton process. This conversion occurs in multiple steps. Firstly, an electron is raised to a first intermediate level by absorption of a first lower-energy photon, from which it is raised into a still higher energy level, directly or after relaxation into a further intermediate level, by absorption of a further, second lower-energy photon. From there, the electron drops back into the base state and emits a higher-energy photon, which has sufficient energy to generate an electron-hole pair in the photovoltaic layer region 1. Because the emission of the photon occurs in all spatial directions, it is particularly favorable if a reflector layer 5 adjoins the interaction layer 4, which reflects photons which were emitted in a spatial angle range facing away from the photovoltaic layer region 1, so that these photons may also pass through the photovoltaic layer region 1. Such a reflector layer 5 advantageously also affects photons which do have sufficient photon energy, but nonetheless have not been absorbed upon a single passage through the photovoltaic layer. These photons are reflected again in the direction of the photovoltaic layer 1 by the reflector layer 5.

The solar cell assembly according to the invention causes a significant increase of the quantum yield and/or the efficiency of a solar cell. The interaction layer 3 can particularly comprise an optically active glass ceramic according to the invention, which is applied as a cover glass on already existing solar cells/solar modules instead of the typical float glass or single-pane safety glasses.

FIG. 2 shows a further exemplary embodiment of a solar cell according to the invention. The photovoltaic layer region 1 has a layer assembly which is parallel to the photon direction of incidence, in contrast to the first exemplary embodiment. The electrodes 2 are also implemented and situated parallel to the photon direction of incidence. This has the great advantage that no requirements in regard to transparency must be placed on the electrodes 2. The combination of such a solar cell with the interaction layers according to the invention occurs similarly to the exemplary embodiment 1. Reference is made to the above description in regard to the explanation of the reference signs already introduced.

### LIST OF REFERENCE NUMERALS

1 Photovoltaic layer region
2 electrodes
3, 4 interaction layers
5 reflector layer
hv incident photons

1-23. (canceled)

24. A solar cell comprising:
at least one photovoltaic layer region, which at least partially absorbs photons incident therein, whose photon energy is greater than a minimum photon energy, and releases electrical charge carriers comprising electron-hole pairs, which are spatially separable within the photovoltaic layer region and can be output from the layer via at least two electrodes, which are electrically connected to the photovoltaic layer region, to provide an electrical voltage, and at least one interaction layer, which at least partially overlaps the photovoltaic layer, in which at least a part of the incident photons are subject to an interaction with emission of photons of higher or lower photon energy than that of the incident photons, wherein the at least one interaction layer includes a matrix structure, with local regions comprising optically active material containing crystalline nanoparticles, with which the incident photons interact, and wherein the crystalline nanoparticles are rare earth element ions.

25. The solar cell according to claim 24,
wherein the matrix structure is amorphous.

26. The solar cell according to claim 25,
wherein the matrix structure is a plastic matrix.

27. The solar cell according to claim 24,
wherein the interaction layer is a glass ceramic comprising a glass matrix.

28. The solar cell according to claim 24,
wherein the optically active material contains nanophosphors.

29. The solar cell according to claim 24,
wherein the optically active material comprises an organic dye.

30. The solar cell according to claim 24,
wherein the photovoltaic layer region has an absorption range which is a function of the photon energy; and
the optically active material is selected so that the photons are emitted when photon energies fall in an absorption range of the photovoltaic layer region.

31. The solar cell according to claim 24,
wherein the at least one interaction layer comprises a cover layer, for protecting the photovoltaic layer region from external influences.

32. The solar cell according to claim 24,
wherein the photovoltaic layer region includes two opposing lateral surfaces, on each of which the interaction layer adjoins indirectly or directly to at least partially overlap the two opposing lateral surface;
one of the at least two interaction layers contains optically active material, providing photons having lower energy than the photon energy of the incident photons which reemitted during interaction of the incident photons with the photovoltaic layer region; and
the other of the at least two interaction layers contains optically active material, providing photons having higher energy than the photon energy of the incident photons which are emitted during interaction of the incident photons with the photovoltaic layer region.

33. The solar cell according to claim 32, wherein:
the other interaction layer is coated with a layer or is adjacent to a non-galvanically connected reflector layer, which at least partially reflects the photons of higher energy and/or the incident photons.

34. The solar cell according to claim 24,
wherein the optically active material interacts with the incident photons during a single-photon or multiphoton process.

35. The solar cell according to claim 24,
wherein the at least one interaction layer is optically transparent in a spectral range from 350 nm to 1100 nm.

36. A method for producing a solar cell including at least one photovoltaic layer region, which at least partially absorbs photons incident therein, whose photon energy is greater than a minimum photon energy, and releases electrical charge carriers comprising electron-hole pairs, which are spatially separable within the photovoltaic layer region and can be output from the layer via at least two electrodes, which are electrically connected to the photovoltaic layer region, to provide an electrical voltage, and at least one interaction layer, which at least partially overlaps the photovoltaic layer, in which at least a part of the incident photons are subject to an interaction with emission of photons of higher or lower photon energy than that of the incident photons, wherein the at least one interaction layer includes a matrix structure, with local regions comprising optically active material containing crystalline nanoparticles, with which the incident photons interact, and wherein the crystalline nanoparticles are rare earth element ions comprising the steps:
providing the at least one interaction layer comprising a matrix structure containing optically active crystalline nanoparticles containing rare earth element ions; and
applying the at least one interaction layer at least partially indirectly or directly on a technical surface of the photovoltaic layer region, or using the at least one interaction layer used as a substrate for applying the photovoltaic layer region.

37. The method according to claim 36,
providing a first interaction layer;
applying the first interaction layer at least partially indirectly or directly on a first technical surface of the photovoltaic layer region, where the first interaction layer is used as a substrate for applying the photovoltaic layer region; and
applying a second interaction layer at least partially indirectly or directly on a second technical surface of the photovoltaic layer.

38. The method according to claim 37, wherein:
providing a technical surface of the first or the second interaction layer at least partially indirectly or directly with a reflector layer.

39. The method according to claim 35, comprising:
providing the at least one interaction layer including a glass-ceramic layer having a glass matrix optically active material containing crystalline nanoparticles.

40. The method according to claim 39, comprising:
providing the at least one interaction layer including a high-temperature glass ceramic; and
using the interaction layer as a substrate material, on which is applied semiconductor layers, forming the photovoltaic layer region, directly during a production process of the photovoltaic layer region.

41. The method according to claim 35,
providing an intermediate layer between the at least one interaction layer and the technical surface of the photovoltaic layer region for providing optical coupling.

42. The method according to claim 35, comprising:
providing the at least one interaction layer by producing a glass melt into which the optically active material is admixed in the form of crystalline nanoparticles.

43. The method according to claim 40, wherein:
the melt comprises fluoride glass to which is added barium, chlorine and rare earth element ions; and
temperature treating the crystalline nanoparticles in the glass to which at least a part of the rare earth element ions adhere or to which at least a part of the rare earth element ions are incorporated.

44. The method according to claim 43, comprising:
adding erbium ions to provide an interaction layer in which photons of lower energy are converted into photons of higher energy.

45. The method according to claim 43, comprising:
adding europium ions to provide an interaction layer in which photons of higher energy are converted into photons of lower energy in a single-photon process.

46. The method according to claim 43, comprising:
adding europium and gadolinium ions to provide an interaction layer in which photons of higher energy are converted into photons of lower energy in a two-photon process.
